(19) United States
(12) Patent Application Publication
(10) Pub. No.: US 2024/0055829 A1
(43) Pub. Date: Feb. 15, 2024

(54) Semiconductor Laser and Design Method Therefor

(71) Applicant: Nippon Telegraph and Telephone Corporation, Tokyo (JP)

(72) Inventors: Takuma Tsurugaya, Musashino-shi, Tokyo (JP); Shinji Matsuo, Musashino-shi, Tokyo (JP)

(21) Appl. No.: 18/259,145

(22) PCT Filed: Jan. 18, 2021
(86) PCT No.: PCT/JP2021/001447

§ 371 Date: Jun. 23, 2023

(51) Int. Cl. H01S 5/14; H01S 3/106; H01S 5/0687

(52) U.S. Cl. CPC H01S 5/141; H01S 3/1062; H01S 5/0687

(57) ABSTRACT

A semiconductor laser includes a first optical waveguide including a first reflection unit and a second reflection unit, and a confinement portion. The first reflection unit and the second reflection unit are waveguide type reflection units each having a structure in which the refractive index is periodically modulated. The first reflection unit, the confinement portion, and the second reflection unit constitute a Fabry-Perot type optical resonator. The semiconductor laser also includes a second optical waveguide disposed along a first optical waveguide to extend from the confinement portion to the second reflection unit side. The second optical waveguide serves as an extraction optical waveguide. Further, a third reflection unit formed continuously with the second optical waveguide is provided at a location corresponding to the first reflection unit.

### TECHNICAL FIELD

The present invention relates to a semiconductor laser and a method of designing the same.

### BACKGROUND ART

As a semiconductor laser that can be compactly integrated with a silicon waveguide (SiWG), a semiconductor laser in which a laser resonator composed of a group III-V compound semiconductor such as InP or GaAs is coupled with a SiWG to enable direct light extraction to the SiWG has been researched and developed (NPL 1, NPL 2, and NPL 3).

In this type of laser resonator, an optical waveguide structure in which a single mode oscillation is enabled by causing Bragg reflection by subjecting an optical waveguide to periodic refractive index modulation to resonate only a specific wavelength component is often used. As one example, a laser in which a periodic refractive index modulation is formed in an active region portion is called a distributed feedback (DFB) laser. In addition, a passive optical waveguide portion surrounding an active region with periodic refractive index modulation is called a distributed Bragg reflector laser (DBR) laser.

In addition, in particular, a laser in which extremely strong Bragg reflection is caused by hollowing out the central part of the optical waveguide to form an extremely compact cavity on the order of microns is called a photonic crystal (PhC) laser.

In these configurations, the extraction optical waveguide having an appropriate equivalent refractive index is arranged in the vicinity of the optical waveguide type lasers to be optically coupled with the laser resonator, and direct light extraction from the laser resonator to the extraction optical waveguide can be realized.

Here, in the optical waveguide type resonator structure, light continues to reciprocate back and forth along the optical waveguide (in a guiding direction), and there are two components of a forward wave component and a backward wave component. On the other hand, when the extraction optical waveguide is brought close, each of the forward wave and the backward wave is coupled with the extraction optical waveguide, and light is output to both the front side and the rear side of the extraction optical waveguide.

### CITATION LIST

### Non Patent Literature

[NPL 1] G. Crosnier et al., “Hybrid indium phosphide-on-silicon nanolaser diode,” Nature Photonics, vol. 11, pp. 297-300, 2017.

[NPL 2] H. Duprez et al., “1310 nm hybrid InP/InGaAsP on silicon distributed feedback laser with high side-mode suppression ratio,” Optics Express, vol. 23, No. 7, pp. 8489-8497, 2015.

[NPL 3] R. Katsumi et al., “Quantum-dot single-photon source on a CMOS silicon photonic chip integrated using transfer printing,” APL Photonics, vol. 4, 036105, 2019.

### SUMMARY OF INVENTION

### Technical Problem

The main application of such a semiconductor laser is a transmitter for information transmission. However, when a signal is sent in one direction from the transmitting side to the receiving side, optical output from the rear side is unnecessary. As a typical example, in the case of a symmetrical emission structure that outputs the same amount of optical power to both the front side and the rear side, 50% of the optical power is lost in principle. In order to achieve both sufficient optical output power (required to obtain a sufficient SNR at the receiver side) and low power consumption (especially important for short distance information transmission), it is important to output light with the highest possible efficiency. However, as described above, in the conventional technology, there is a problem that loss occurs in the output optical power.

An object of the present invention is to solve the above problems, and to prevent loss of optical power of a semiconductor laser.

### Solution to Problem

A semiconductor laser according to the present invention includes a first optical waveguide including a waveguide-type first and second reflection units each having a structure in which a refractive index is periodically modulated, and a confinement portion sandwiched between the first reflection unit and the second reflection unit, a second optical waveguide disposed along the first optical waveguide to extend from the confinement portion toward the second reflection unit side, a third reflection unit formed continuously with the second optical waveguide at a location corresponding to the first reflection unit, and an active layer formed in the confinement portion, in which a Fabry-Perot optical resonator is configured by the first reflection unit, the confinement portion, and the second reflection unit, and in a coupling region where the confinement portion is disposed, the second optical waveguide and the confinement portion are in a state capable of optically coupling with each other, and a laser is output to the side of the second reflection unit of the second optical waveguide.

In addition, a method of designing the semiconductor laser according to the present invention includes setting, when a position offset in a waveguide direction between the first reflection unit and the third reflection unit is denoted as L_{Φ}, a propagation constant of a portion of the length L_{Φ} in the second optical waveguide of a portion of a position offset in a waveguide direction between the first reflection unit and the third reflection unit is denoted as β_{Φ}, a propagation constant of the coupling region in the first optical waveguide is denoted as β_{A}, and a propagation constant of the coupling region in the second optical waveguide is denoted as β_{B},

Math. 1
The endpoint of the coupling region on the laser output side is denoted as subscript F, the endpoint on the opposite side is denoted as subscript R, in an optical electric field in the first optical waveguide and the second optical waveguide in the coupling region, forward wave components are denoted as \vec{A _{F}}, \vec{A_{R}}, \vec{B_{F}}, and \vec{B_{R}}, and backward wave components are denoted as [symbol] , [symbol] , [symbol] , and [symbol] and following equations are provided:

$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} and ( \begin{matrix}\vec{{A}_{F}} \\ \vec{{B}_{F}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( A )$$

$${c}_{11} = {r}_{F , A} {r}_{R , A} [ {\{ cos ( q {L}_{c} ) + j \frac{δ}{q} sin ( q {L}_{c} ) \}}^{2} - \frac{{χ}^{2}}{{q}^{2}} {sin}^{2} ( q {L}_{c} ) {e}^{- 2 j {β}_{Φ} {L}_{Φ}} ] {e}^{- j ( {β}_{A} + {β}_{B} ) {L}_{c}} \qquad ( B )$$

a condition so that a state of a wavelength satisfying a resonance condition obtained on the basis of wavelength characteristics of c₁₁ obtained by changing χ and L_{Φ} satisfies a single mode condition based on Equations A and B.

### Advantageous Effects of Invention

As described above, according to the present invention, since the third reflection unit is provided in the second optical waveguide disposed along the first optical waveguide having the confinement portion in which the active layer is formed, the loss of the optical power of the semiconductor laser can be prevented.

### BRIEF DESCRIPTION OF DRAWINGS

FIG. 1A is a cross-sectional view illustrating a configuration of a semiconductor laser according to the embodiment of the present invention.

FIG. 1B is a plan view illustrating a partial configuration of the semiconductor laser according to the embodiment of the present invention.

FIG. 1C is a plan view illustrating a partial configuration of the semiconductor laser according to the embodiment of the present invention.

FIG. 2A is a cross-sectional view illustrating a configuration of another semiconductor laser according to the embodiment of the present invention.

FIG. 2B is a plan view illustrating a partial configuration of another semiconductor laser according to the embodiment of the present invention.

FIG. 2C is a plan view illustrating a partial configuration of another semiconductor laser according to the embodiment of the present invention.

FIG. 3A is a plan view illustrating a partial configuration of another semiconductor laser according to the embodiment of the present invention.

FIG. 3B is a plan view illustrating a partial configuration of another semiconductor laser according to the embodiment of the invention.

FIG. 4A is a plan view illustrating a partial configuration of another semiconductor laser according to the embodiment of the invention.

FIG. 4B is a cross-sectional view illustrating a partial configuration of another semiconductor laser according to the embodiment of the present invention.

FIG. 5 is a configuration diagram illustrating a model used for analysis for designing the semiconductor laser.

FIG. 6A is a characteristic diagram illustrating wavelength characteristics of c11 when various values are set for parameters χ representing coupling strength between a first optical waveguide A and a second optical waveguide B in a coupling region 132 and a phase adjustment length L_{Φ} are set to various values.

FIG. 6B is a characteristic diagram illustrating wavelength characteristics of c11 when various values are set for parameters χ representing coupling strength between the first optical waveguide A and the second optical waveguide B in the coupling region 132 and the phase adjustment length LΦ.

FIG. 6C is a characteristic diagram illustrating wavelength characteristics of c11 when various values are set for parameters χ representing coupling strength between the first optical waveguide A and the second optical waveguide B in the coupling region 132 and the phase adjustment length L_{Φ}.

FIG. 7 is an explanatory diagram illustrating a configuration of a simulation setup for numerical simulation by a three-dimensional finite-difference time-domain method (3D-FDTD method).

FIG. 8 is a characteristic diagram illustrating L_{Φ} dependency of a resonator Q value obtained by simulation.

FIG. 9 is a characteristic diagram illustrating L_{Φ} dependency of light extraction efficiency obtained by simulation.

FIG. 10 is a distribution diagram illustrating an optical field intensity distribution of a y-z cross-section at an x-coordinate center of the first optical waveguide A and the second optical waveguide B of a resonance mode obtained by performing 3D-FDTD calculation.

FIG. 11 is a distribution diagram illustrating an optical field intensity distribution of an x-z cross-section at a y-coordinate center of the second optical waveguide B of the resonance mode obtained by performing 3D-FDTD calculation.

FIG. 12 is a characteristic diagram illustrating resonator characteristics when values of reflectances |r_{F, A}|² and |r_{R, A}|² of the third reflection unit 131 are changed to change an isolated resonator Q value of a Fabry-Perot resonator given by Equation (16).

FIG. 13 is a characteristic diagram illustrating resonator characteristics when values of reflectances |r_{F, A}|² and |r_{R, A}|² of the third reflection unit 131 are changed to change the isolated resonator Q value of the Fabry-Perot resonator given by Equation (16).

FIG. 14 is a plan view illustrating a partial configuration of another semiconductor laser according to the embodiment of the present invention.

### DESCRIPTION OF EMBODIMENTS

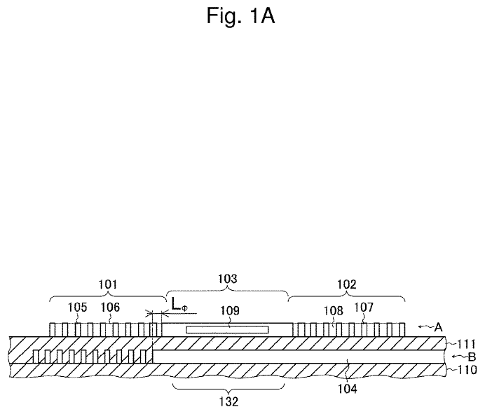

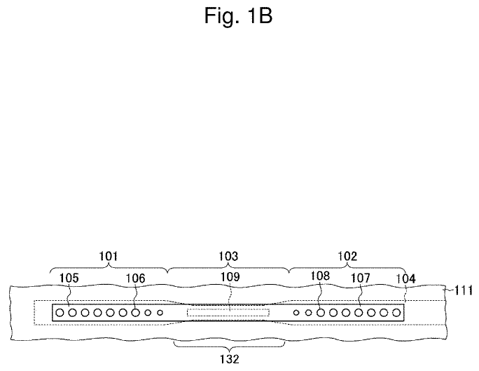

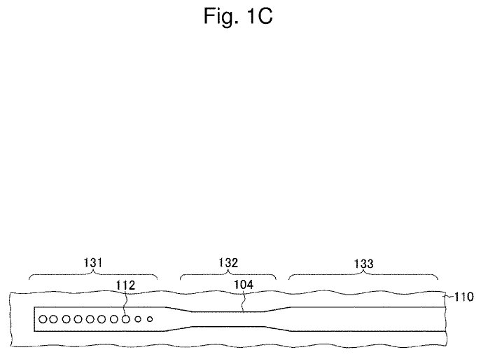

Hereinafter, a semiconductor laser according to an embodiment of the present invention will be described with reference to FIGS. 1A, 1B, and 1C. The semiconductor laser includes a first optical waveguide A including a first reflection unit 101, a second reflection unit 102, and a confinement portion 103.

The first reflection unit 101 and the second reflection unit 102 are configured of a structure in which a refractive index is periodically modulated, and are formed into a waveguide type. The first reflection unit 101 and the second reflection unit 102 are configured of a thin-wire waveguide-type one-dimensional photonic crystal.

In this case, the waveguide-type photonic crystal (a one-dimensional photonic crystal) configuring the first reflection unit 101 includes a first base 105 and first lattice elements 106 formed in the first base 105. The first lattice elements 106 are linearly and periodically provided at predetermined intervals, have a refractive index different from that of the first base 105, and have a columnar shape (for example, a cylindrical shape). For example, the first lattice element 106 is a through-hole formed in the first base 105.

Similarly, the one-dimensional photonic crystal forming the second reflection unit 102 includes a second base 107 and second lattice elements 108 formed on the second base 107. The second lattice elements 108 are linearly and periodically provided at predetermined intervals, have a refractive index different from that of the second base 107, and have a columnar shape (for example, a cylindrical shape). For example, the second lattice element 108 is a through-hole formed in the second base 107.

The first reflection unit 101, the confinement portion 103, and the second reflection unit 102 configure a Fabry-Perot type optical resonator. For example, the first base 105, the confinement portion 103, and the second base 107 are integrally formed of the same material and the confinement portion 103 is a portion where the lattice elements described above are not formed. An active layer 109 is formed (buried) in the confinement portion 103. The external form of the active layer 109 is, for example, a rectangular parallelepiped.

The first base 105, the confinement portion 103, and the second base 107 can be configured of, for example, InP. An integrated structure configuring the first base 105, the confinement portion 103, and the second base 107 can be, for example, a core-like structure with a width of 500 nm and a thickness of 250 nm.

In addition, for example, when a resonance wavelength is set to a 1.55 μm band which is suitable for communication applications, lattice constants of the first reflection unit 101 and the second reflection unit 102 can be set to around 375 nm to 455 nm. Furthermore, diameters of the first lattice element 106 and the second lattice element 108 can be set to 180 nm. Since the first base 105, the confinement portion 103, and the second base 107 are given a core shape with a thickness of 250 nm, the first lattice element 106 and the second lattice element 108 form a cylinder with a diameter of 180 nm and a height of 250 nmn.

In addition, the semiconductor laser further includes a second optical waveguide B disposed along the first optical waveguide A to extend from the confinement portion 103 to the second reflection unit 102 side. The second optical waveguide B serves as an extraction optical waveguide. Further, a third reflection unit 131 formed continuously with the second optical waveguide B is provided at a location corresponding to the first reflection unit 101. The third reflection unit 131 has reflection characteristics similar to those of the first reflection unit 101. In this example, the third reflection unit 131 is formed of a waveguide type one-dimensional photonic crystal, like the first reflection unit 101 described above. In this case, the waveguide type photonic crystal (one-dimensional photonic crystal) forming the third reflection unit 131 is configured to include a third lattice element 112 formed in a core 104 of the second optical waveguide B. A region where the third lattice element 112 is formed is a portion extending from the core 104 to a region of the third reflection unit 131.

Here, in a coupling region 132 where the confinement portion 103 is disposed, the second optical waveguide B and the confinement portion 103 are in a state capable of optically coupling with each other. In this semiconductor laser, the laser is output to the second reflection unit 102 side of the second optical waveguide B.

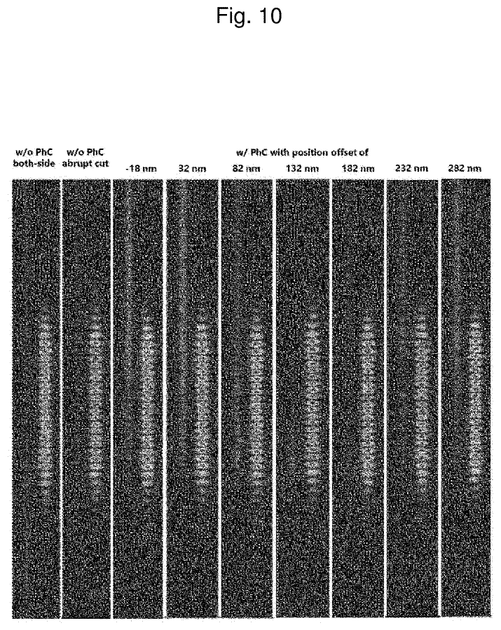

The core 104 is configured of, for example, silicon. The core 104 is formed on a lower clad layer 110. An upper clad layer 111 is formed on the lower clad layer 110 so as to cover the core 104. Each clad layer is formed of, for example, silicon oxide. In the embodiment, the first optical waveguide A is formed on the upper clad layer 111. FIG. 1A illustrates a cross-section parallel to the waveguide direction and perpendicular to the plane of the lower clad layer 110 (upper clad layer 111). In addition, FIG. 1B illustrates a plane on the upper clad layer 111. Furthermore, FIG. 10 illustrates a plane on the lower clad layer 110.

For example, the core-like integral structure configuring the first base 105, the confinement portion 103, and the second base 107 described above is formed, for example, on the upper clad layer 111 by the well-known metalorganic chemical vapor deposition method can be formed by depositing InP.

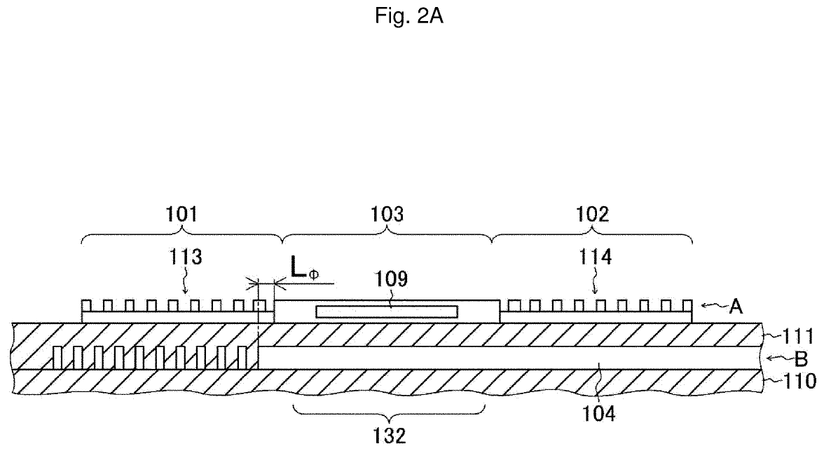

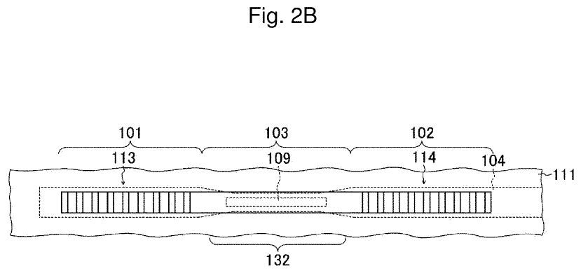

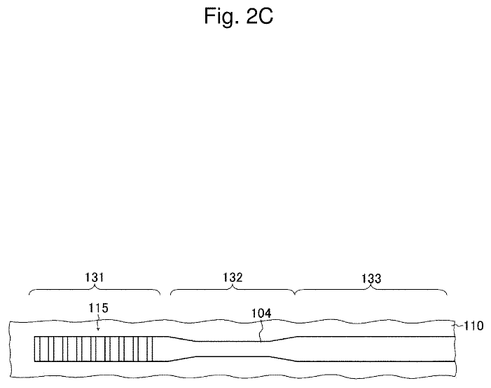

In addition, in this semiconductor laser, as illustrated in FIGS. 2A, 2B, and 2C, the first reflection unit 101 is formed from a first diffraction grating 113 formed on the core of the first reflection unit 101 of the first optical waveguide A. In addition, the second reflection unit 102 can be configured of a second diffraction grating 114 formed on the core in the second reflection unit 102 of the first optical waveguide A. Similarly, the third reflection unit 131 can be configured of a third diffraction grating 115 formed on the core 104 in the second optical waveguide B. A region where the third diffraction grating 115 is formed is a portion where the core 104 extends to a region of the third reflection unit 131.

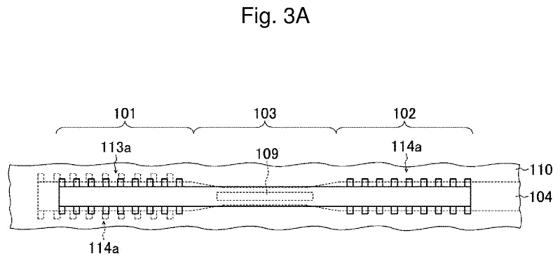

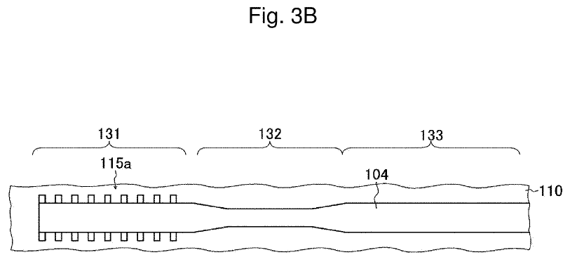

In addition, in the semiconductor laser, as illustrated in FIGS. 3A and 3B, the first reflection unit 101 can be configured of a first diffraction grating 113a formed on both side surfaces of the core in the first reflection unit 101 of the first optical waveguide A. The second reflection unit 102 can be configured of a second diffraction grating 114a formed on both side faces of the core in the second reflection unit 102 of the first optical waveguide A. Similarly, the third reflection unit 131 can be configured of third diffraction gratings 115a formed on both side surfaces of the core 104 of the second optical waveguide B. The region where the third diffraction grating 115a is formed is a part where the core 104 is extended to the region of the third reflection unit 131.

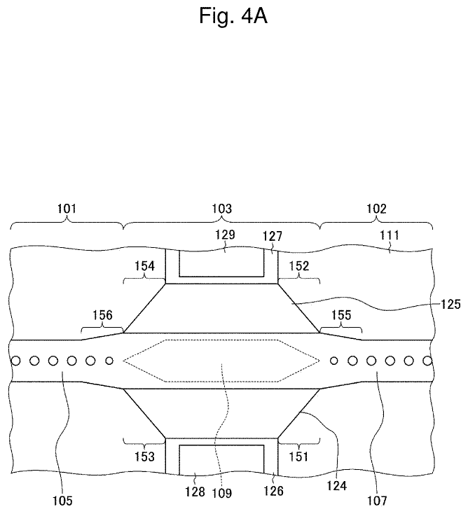

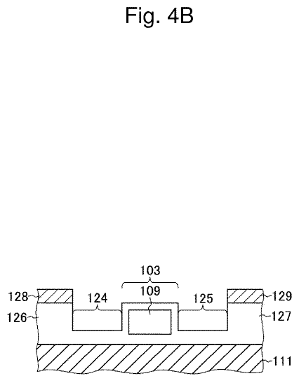

Next, current injection in the confinement portion 103 will be described with reference to FIGS. 4A and 4B. Meanwhile, FIG. 4B illustrates a cross-section of a surface perpendicular to a waveguide direction. The current injection structure can be realized by a first semiconductor layer 124 and a second semiconductor layer 125. The first semiconductor layer 124 and the second semiconductor layer 125 are formed on the upper clad layer 111 and are formed in parallel to the surface of the upper clad layer 111 and perpendicular to the waveguide direction, sandwiching the confinement portion 103 and in contact with the side surfaces of the confinement portion 103. The first semiconductor layer 124 can be composed of, for example, an n-type III-V group compound semiconductor such as n-type InP. In addition, the second semiconductor layer 125 can be composed of, for example, a p-type III-V group compound semiconductor such as p-type InP.

In addition, the current injection structure includes a first contact layer 126 formed on the upper clad layer 111 and connected to the first semiconductor layer 124 arranged to sandwich the first semiconductor layer 124 with the confinement portion 103 and a second contact layer 127 formed on the upper clad layer 111 and connected to the second semiconductor layer 125 arranged to sandwich the second semiconductor layer 125 with the confinement portion 103, and the first contact layer 126 can be composed of an n-type III-V group compound semiconductor such as n-type InP. In addition, the second contact layer 127 can be composed of a p-type III-V group compound semiconductor such as p-type InP.

Furthermore, the current injection structure includes a first electrode 128 electrically connected to the first contact layer 126 and a second electrode 129 electrically connected to the second contact layer 127.

In this current injection structure, first, the first semiconductor layer 124 and the second semiconductor layer 125 can be formed thinner than the confinement portion 103 having a core-like structure.

Note that, the active layer 109 can have a shape in which the end portion in the waveguide direction tapers toward the tip. In this example, the active layer 109 has a shape in which both ends thereof in the waveguide direction taper. Meanwhile, the waveguide direction is a right-left direction of the paper in FIG. 4A.

Further, the first semiconductor layer 124 has a trapezoidal shape in which the width becomes narrower from the confinement portion 103 side to the first contact layer 126 side in a plan view, and one end in the wave-guiding direction can be configured to have a first tapered region 151 whose width becomes narrower as it moves away from the central portion of the confinement portion 103. Similarly, the second semiconductor layer 125 can include a second tapered region 152 having a trapezoidal shape in which the width thereof decreases toward the side of the second contact layer 127 from the side of the confinement portion 103 when seen in a plan view and the width thereof decreases as an end in the waveguide direction recedes from the central portion of the confinement portion 103.

Further, in this example, the first semiconductor layer 124 can include a third tapered region 153 in which the width thereof decreases as the other end in the waveguide direction recedes from the central portion of the confinement portion 103. Similarly, the second semiconductor layer 125 can include a fourth tapered region 154 in which the width thereof decreases as the other end in the waveguide direction recedes from the central portion of the confinement portion 103. In this example, the first semiconductor layer 124 and the second semiconductor layer 125 have an isosceles trapezoidal shape in which the side of the active layer 109 is the base when seen in a plan view.

In addition, the confinement portion 103 can be configured to include a fifth tapered region 155, at one end of the confinement portion 103, whose width gradually becomes narrower in a plan view as it is separated from the confinement portion 103. The confinement portion 103 can be configured to include a sixth tapered region 156 which gradually narrows in width in a plan view as it goes away from the confinement portion 103, at the other end of the confinement portion 103. In this example, the first reflection unit 101 and the second reflection unit 102 disposed in the waveguide direction with the confinement portion 103 interposed therebetween can be optically connected to the active layer 109 (the confinement portion 103) via the fifth tapered region 155 and the sixth tapered region 156. The core widths of the first reflection unit 101 and the second reflection unit 102 may be the same as the core width of the confinement portion 103.

When the manufacture of the above-mentioned structure is described briefly, for example, a thin semiconductor layer formed of InP is formed on the clad layer 111, and then an InP-based semiconductor layer or a semiconductor laminated structure serving as the active layer 109 is formed thereon. The semiconductor laminated structure is, for example, a multiple quantum well structure. Thereafter, the active layer 109 is formed by patterning the InP-based semiconductor layer or the semiconductor laminated structure serving as the active layer 109 by known lithography technology and etching technology.

Next, the active layer 109 is formed, and the InP is regrown from the thin semiconductor layer made of the InP exposed around the active layer 109 to form a thick semiconductor layer in which the active layer 109 is embedded, impurity introduction is performed to form regions of each conductivity type. Next, a region serving as the first semiconductor layer 124 and the second semiconductor layer 125, and a region serving as the first contact layer 126, and the second contact layer 127 are formed by known lithography and etching techniques. In this process, the shapes of the confinement portion 103 of the first reflection unit 101 and the second reflection unit 102 and the confinement portion 103 of the fifth tapered region 155 and the sixth tapered region 156 are formed. In the first reflection unit 101, the second reflection unit 102, the fifth tapered region 155, and the sixth tapered region 156, the InP (semiconductor) in the region other than the confinement portion 103 is completely removed to expose the upper surface of the upper clad layer 111.

Thereafter, a groove is formed in each of the regions that become the first semiconductor layer 124 and the second semiconductor layer 125 to make the layers thin by known lithography technology and etching technology, and thus it is possible to form the first semiconductor layer 124 and the second semiconductor layer 125, and the first contact layer 126 and the second contact layer 127 that are subsequent thereto. In this case, an optical waveguide referred to as a so-called rib type is formed.

Meanwhile, after the groove is formed in each of the regions that become the first semiconductor layer 124 and the second semiconductor layer 125 to make the layers thin, the regions that become the first semiconductor layer 124 and the second semiconductor layer 125 and the regions that become the first contact layer 126 and the second contact layer 127 can also be formed. In the confinement portion 103, the first semiconductor layer 124 and the second semiconductor layer 125 with the confinement portion 103 interposed therebetween can be made thinner than the confinement portion 103, and thus light confinement with respect to the confinement portion 103 in a direction parallel to the surface of the clad layer 111 and perpendicular to the waveguide direction can be increased as compared with in the case of these having the same thickness.

Localization of a mode field also brings a desirable effect from the viewpoint of reducing element resistance. That is, in the current injection structure described above, if the mode field of the first optical waveguide A overlaps with the electrode portion, a large optical loss is caused due to this. For this reason, it is important to pull the electrode away from the core to a point where the mode field is not affected by its presence. In this regard, in the current injection structure in which the thickness of the core and the semiconductor layers on both sides thereof are equal, a mode field extends in a horizontal direction as described above, and thus, it is necessary to dispose the electrodes at distant locations accordingly.

On the other hand, according to the current injection structure described above, the mode field is also strongly localized in the lateral direction, so the first electrode 128 and the second electrode 129 can be brought closer to the confinement portion 103. In an active current injection structure configured of p-type InP, an InP-based active layer, and n-type InP, p-type InP has a particularly high resistivity, and the element resistance is governed by the doping concentration and shape of the p-type InP region. According to this current injection structure, since the p-type second semiconductor layer 125 can be made thinner than the confinement portion 103, the resistance of this region is increased. On the other hand, since the first electrode 128 and the second electrode 129 can be brought close to the confinement portion 103, an increase in a resistance value due to the thinning can be offset by a reduction in the length of a conduction path. As a result, it is possible to realize element resistance at the same level or lower than in the related art in which a core and semiconductor layers have the same thickness.

Next, an optical connection among the confinement portion 103, the first reflection unit 101, and the second reflection unit 102 will be described. In the above-described structure, the first reflection unit 101 and the second reflection unit 102 can be connected to the confinement portion 103 very efficiently by the tapered region.

In order to efficiently achieve optical coupling between the first optical waveguide A and the second optical waveguide B in the coupling region 132, the following structure can be adopted.

A difference Δ1 between an equivalent refractive index of the second reflection unit 102 of the first optical waveguide A and the equivalent refractive index of the core 104 of an emission-side region 133 corresponding to this region is made larger than a difference Δ2 between the equivalent refractive index of the confinement portion 103 and the equivalent refractive index of the core 104 in a third region 123 corresponding to the confinement portion 103.

With the above-described configuration, the first optical waveguide A and the second optical waveguide B are optically coupled (optically coupled) in the coupling region 132, but are not optically coupled in other regions.

For example, by setting the diameter of the core 104 of the coupling region 132 different from that of the other regions, the relationship of the difference in equivalent refractive index described above can be established. For example, the core 104 in the coupling region 132 has a smaller diameter than the cores 104 in other regions, thereby making Δ1 larger than Δ2. For example, in a plan view, the width of the core 104 can be made larger than the width of the first reflection unit 101 and the second reflection unit 102.

As described above, by controlling the diameter of the core 104, while the optical separation between the second optical waveguide B and the first optical waveguide A is maintained, they van be optically coupled in the coupling region 132 with arbitrary strength.

In addition, the core 104 can be configured such that the diameter gradually changes from the coupling region 132 to the emission-side region 133. With this configuration, the strength of optical coupling between the core 104 and the optical resonator can be gradually (adiabatically) changed. Shapes of modes differ between the first and second reflection units 101 and 102 and the confinement portion 103 and, generally, radiation loss due to a mode mismatch between the first and second reflection units 101 and 102 and the confinement portion 103 can be present. Conversely, by imparting an adiabatic change in shape as described above, a configuration in which modes are adiabatically converted can be adopted and a reduction in radiation loss due to a mode mismatch can be achieved.

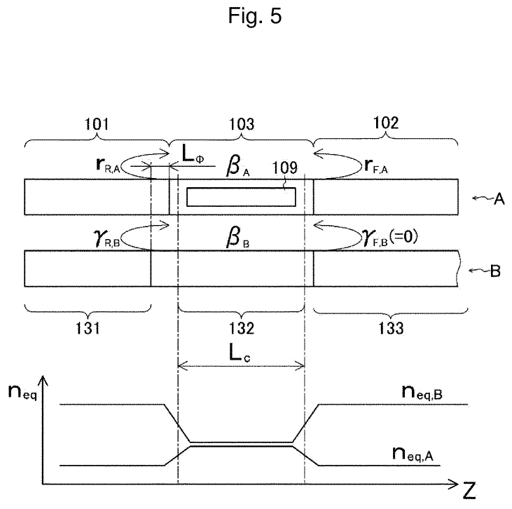

Next, a method of designing the semiconductor laser according to an embodiment of the present invention will be described. First, the characteristics of the resonator structure of the semiconductor laser described above will be described. In the analysis of this structure, the model illustrated in FIG. 5 is used. In FIG. 5, a subscript A is related to the first optical waveguide A, and a subscript B is related to the second optical waveguide B. In addition, a subscript F means the front side from which light is emitted, and a subscript R means the rear side on the side where the third reflection unit 131 is formed.

In addition, L_{Φ} is a positional offset in the z-axis direction (guiding direction) between the first reflection unit 101 arranged on the rear side of the first optical waveguide A and the third reflection unit 131 of the second optical waveguide B. Further, n_{eq, A} is an equivalent refractive index of the first optical waveguide A and n_{eq , B} is an equivalent refractive index of the second optical waveguide B. Moreover, β_{A}=(2πn_{eq, A})/λ is a propagation constant in the coupling region 132 of the first optical waveguide A and β_{B}=(2πn_{eq, B})/λ is a propagation constant in the coupling region 132 of the second optical waveguide B. In addition, L_{C} is an effective coupling length as a directional coupler between the first optical waveguide A and the second optical waveguide B in the coupling region 132 obtained as a result of these matching.

In addition, γ_{R, A} is amplitude reflectance from the end of the coupling region 132 to the side of the first reflection unit 101 in the first optical waveguide A. γ_{F,A} is amplitude reflectance from the end of the coupling region 132 to the side of the second reflection unit 102 in the first optical waveguide A. γ_{R,B} is amplitude reflectance from the end of the coupling region 132 to the side of the third reflection unit 131 in the second optical waveguide B. γ_{F,A} is amplitude reflectance from the end of the coupling region 132 to the emission-side region 133 in the second optical waveguide B.

In a region outside the coupling region 132, a difference in equivalent refractive index between the first optical waveguide A and the second optical waveguide B is sufficiently large, and optical coupling does not occur, and it is necessary to pay attention that the optical waveguide behaves as an independent optical waveguide.

Math. 2
Furthermore, the forward wave components (+z direction) of the optical electric fields of the first optical waveguide A and the second optical waveguide B at the end points of the coupling region 132 (the front side end point is denoted as subscript F, and the rear side end point is denoted as subscript R) are represented by \vec{A_{F}}, \vec{A_{R}}, \vec{B_{F}}, and \vec{B_{R}} and the backward wave components (−z direction) thereof are represented by [symbol] , [symbol] , [symbol] , and [symbol] Then, regarding the coupling region as a directional coupler, the following relationship is established.

$$Math . 3$$

$$( \begin{matrix}\vec{{A}_{F}} \\ \vec{{B}_{F}}\end{matrix} ) ≡ {C}_{DC} ( \begin{matrix}\vec{{A}_{R}} \\ \vec{{B}_{R}}\end{matrix} ) \cdot ( \begin{matrix}\overleftarrow{{A}_{R}} \\ \overleftarrow{{B}_{R}}\end{matrix} ) = {C}_{DC} ( \begin{matrix}\overleftarrow{{A}_{F}} \\ \overleftarrow{{B}_{F}}\end{matrix} ) \qquad ( 1 )$$

Here, C_{DC} is a matrix representing the mixing of the optical electric field between the first optical waveguide A and the second optical waveguide B due to directional coupling, and is given by the following equation:

$${C}_{DC} = {e}^{- j \frac{{β}_{A} + {β}_{B}}{2} {L}_{c}} ( \begin{matrix}cos ( q {L}_{c} ) + j \frac{δ}{q} sin ( q {L}_{c} ) & - j \frac{χ}{q} sin ( q {L}_{c} ) \\ - j \frac{χ}{q} sin ( q {L}_{c} ) & cos ( q {L}_{c} ) - j \frac{δ}{q} sin ( q {L}_{c} )\end{matrix} ) \qquad ( 2 )$$

$$At this time , the following equations are established :$$

$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} .$$

β_{A} and β_{B} are propagation constants when the optical waveguides independently exist and no optical coupling occurs. On the other hand, β_{A}′ and β_{B}′ are propagation constants of the respective super modes when both of them exist and optical coupling occurs to form super modes which are confined in the entire structure and have a distribution in both optical waveguides.

Math. 4
Then, considering the round trip in the resonator, it can be seen that the relationship between the optical electric fields \vec{A_{F,0}} and \vec{B_{F,0}}, before the round trip and the optical electric fields \vec{A_{F}} and \vec{B_{F}}, after the round trip is established.

$$( \begin{matrix}\vec{{A}_{F}} \\ \vec{{B}_{F}}\end{matrix} ) ≡ {C}_{DC} ( \begin{matrix}{r}_{R , A} & 0 \\ 0 & {r}_{R , B}\end{matrix} ) {C}_{DC} ( \begin{matrix}{r}_{F , A} & 0 \\ 0 & {r}_{F , B}\end{matrix} ) ( \begin{matrix}\vec{{A}_{F , 0}} \\ \vec{{B}_{F , 0}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( 3 )$$

Here, since the resonance condition of the resonator is that the phase of the optical electric field returns to the original state when the optical electric field makes a round trip, the following equation is given:

Math. 5

\vec{A_{F}}α\vec{A_{F,0}},\vec{B_{F}}=b\vec{B_{F,0}} (4)

a and b are appropriate positive real numbers representing the change (amplification or attenuation) of the optical electric field intensity in each of the first optical waveguide A and the second optical waveguide B. At this time, since a mode satisfying the resonance condition, that is, a spatial distribution of the resonance mode is always constant irrespective of time, the change in the optical electric field intensity when the resonance mode makes a round trip is also constant irrespective of the spatial coordinates, and it can be seen that a=b. Therefore, from Equations (3) and (4), the resonance condition can be expressed in the form of the following characteristic equation.

$$Math . 6$$

$$( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) = a ( \begin{matrix}\vec{{A}_{F , 0}} \\ \vec{{B}_{F , 0}}\end{matrix} ) \qquad ( 5 )$$

This matrix

$$( \begin{matrix}{c}_{11} & {c}_{12} \\ {c}_{21} & {c}_{22}\end{matrix} )$$

can be diagonalized with

$${P}^{- 1} ( \begin{matrix}{c}_{11} & {c}_{12} \\ {c}_{21} & {c}_{22}\end{matrix} ) P = ( \begin{matrix}{c}_{+} & 0 \\ 0 & {c}_{-}\end{matrix} )$$

by the diagonalization matrix P in which these eigenvectors are arranged. Here, c₊ and c₋ are eigenvectors and the following equation is established (reverse order):

$${c}_{\pm } = \frac{{c}_{11} + {c}_{22} \pm \sqrt{{( {c}_{11} - {c}_{22} )}^{2} + 4 {c}_{12} {c}_{21}}}{2} \qquad ( 6 )$$

Math. 7
Accordingly, when newly defining optical electric fields \vec{A₊} and \vec{B₋} considering mixing the optical electric fields between the first optical waveguide A and the second optical waveguide B by the following equation:

$$( \begin{matrix}\vec{{A}_{+}} \\ \vec{{B}_{-}}\end{matrix} ) ≡ {P}^{- 1} ( \begin{matrix}\vec{{A}_{F , 0}} \\ \vec{{B}_{F , 0}}\end{matrix} ) , \qquad ( 7 )$$

the following equation obtained:

$$( \begin{matrix}{c}_{+} & 0 \\ 0 & {c}_{-}\end{matrix} ) ( \begin{matrix}\vec{{A}_{+}} \\ \vec{{B}_{-}}\end{matrix} ) = a ( \begin{matrix}\vec{{A}_{+}} \\ \vec{{B}_{-}}\end{matrix} ) , \qquad ( 8 )$$

and it can be found that two independent natural resonance modes: c₊\vec{A₊}=α\vec{A₊} and c₋\vec{B₋}=α\vec{B₋} are formed.

At this time, in the semiconductor laser according to the embodiment, since the reflection of light does not occur on the front side of the second optical waveguide B, γ_{F, B}=0, therefore, c₂₂=c₂₁=0 is established.

Math. 8
Then, it can be considered that the equations c₊=c₁₁, c₋=0 are obtained, there is no natural resonance mode corresponding to the optical electric field \vec{B₋}, and there is only the following equation as the only natural resonance mode:

c₁₁\vec{A₊}=α\vec{A₊} (9)

It is important that only a single resonance mode exists in order to obtain single mode oscillation.

At this time, c₁₁ is expressed by Equation (3):

$$\begin{matrix}Math . 9 & \\ {c}_{11} = {r}_{F , A} [ {r}_{R , A} {\{ cos ( {qL}_{c} ) + j \frac{δ}{q} sin ( {qL}_{c} ) \}}^{2} - {r}_{R , B} \frac{{χ}^{2}}{{q}^{2}} {sin}^{2} ( q {L}_{c} ) ] \\ {e}^{- j ( {β}_{A} + {β}_{B} ) {L}_{c}} & ( 10 )\end{matrix}$$

From this equation, it can be seen that a reflected wave from the first reflection unit 101 on the rear side of the first optical waveguide A and a reflected wave from the third reflection unit 131 on the rear side of the second optical waveguide B coherently interfere with each other through directional coupling in the coupling region 132, thereby forming one natural resonance mode.

In order to facilitate analysis, it is assumed that the first reflection unit 101 of the first optical waveguide A and the third reflection unit 131 of the second optical waveguide B have the same reflection characteristics. Then,

$$\begin{matrix}Math . 10 & \\ {r}_{R , B} = {r}_{R , A} {e}^{- 2 j {β}_{Φ} {L}_{Φ}} & ( 11 )\end{matrix}$$

can be expressed. β_{Φ} is a propagation constant of a phase adjustment region having a length L_{Φ} in the second optical waveguide B. When this is used, Equation (10) can be rewritten as following equation:

$$\begin{matrix}Math . 11 & \\ {c}_{11} = {r}_{F , A} {r}_{R , A} [ {\{ cos ( {qL}_{c} ) + j \frac{δ}{q} sin ( {qL}_{c} ) \}}^{2} - \frac{{χ}^{2}}{{q}^{2}} {sin}^{2} ( q {L}_{c} ) {e}^{- 2 j {β}_{Φ} {L}_{Φ}} ] & ( 12 )\end{matrix}$$

$${e}^{- j ( {β}_{A} + {β}_{B} ) {L}_{c}}$$

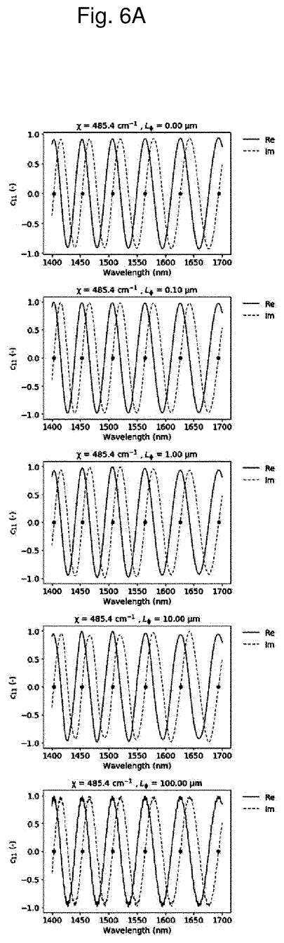

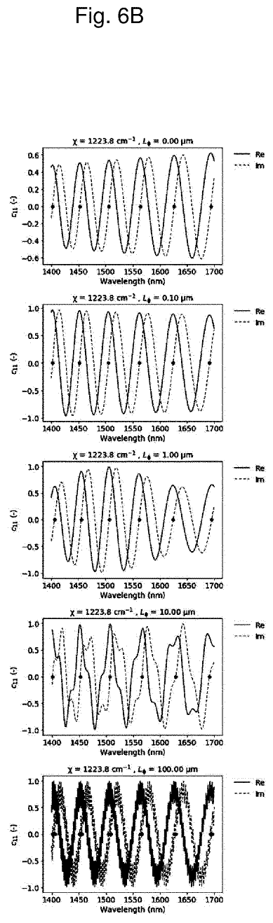

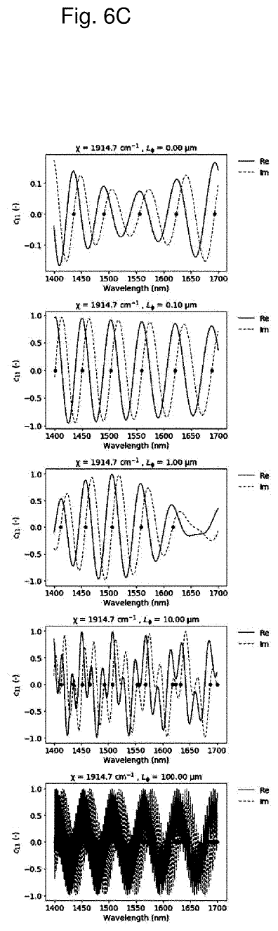

The characteristics of this resonator will be specifically described below based on Equation (12). From Equation (9), the resonance condition is arg[c₁₁]=0, and the phase of Equation (12) determines the longitudinal mode. Therefore, FIGS. 6A, 6B, and 6C show the wavelength characteristics of c₁₁ when various values are set using χ representing the coupling strength between the first optical waveguide A and the second optical waveguide B in the coupling region 132 and the phase adjustment length L_{Φ} as parameters. The circled dots indicate the wavelengths that satisfy the resonance conditions. A state (rough state) with fewer dots and wider intervals between them is closer to the single mode condition, and a state with more dots and narrower intervals (dense state) is a multimode transmission state.

In addition, various parameters assumed in calculating the characteristics of FIGS. 6A, 6B and 6C are illustrated in Table 1. The equivalent refractive indices and the values of δ, q, and χ in Table 1 correspond to FIG. 6A. In calculating the central and right columns having different values of χ, the value of χ is changed by changing the values of the equivalent refractive indices n_{A}′ and n_{B}′ of the super mode when the first optical waveguide A and the second optical waveguide B are coupled in the coupling region 132.

TABLE 1

| Parameter | Value | | Remark |
|---|---|---|---|
| λ₀ | 1.551 | μm | Reference wavelength |
| n_{eq, A} @ λ₀ | 2.563847 | | When A exists alone |
| n_{eq, B} @ λ₀ | 2.569930 | | When B exists alone |
| n_{eq, A}′ @ λ₀ | 2.552564 | | When connecting between A and B |
| n_{eq, B}′ @ λ₀ | 2.577286 | | When connecting between A and B |
| δ @ λ₀ | 123.2 | cm⁻¹ | |
| q @ λ₀ | 500.8 | cm⁻¹ | |
| χ @ λ₀ | 485.4 | cm⁻¹ | |
| ∂n_{eq}/∂λ | −0.733 | μm⁻¹ | Using when calculating |
| | | | wavelength characteristics. |
| | | | Common to A and B |
| L_{C} | 4.0 | μm | |

| | |
|---|---|
| \|r_{F, A}\|² | 0.9926 |
| \|r_{R, A}\|² | 0.9926 |
| \|r_{F, B}\|² | 0 |
| \|r_{R, B}\|² | 0.9926 |

As illustrated in FIG. 6, if χ is small and the phase adjustment length L_{Φ} is short, c₁₁ is not strongly affected by the reflected wave from the rear side of the second optical waveguide B, and a wide longitudinal mode interval (Free Spectral Range: FSR) almost the same as that of the isolated resonator can be obtained.

On the other hand, when χ becomes large, contribution of the reflected wave from the rear side of the second optical waveguide B becomes large, and as a result of interference with the reflected wave from the rear side of the first optical waveguide A, the wavelength characteristic of C₁₁ shows waviness. Further, if L_{Φ} is made longer, a long resonator is formed between the front side of the first optical waveguide A and the rear side of the second optical waveguide B, and various longitudinal modes exist, and the FSR is narrowed.

In general, in a composite resonator having three or more reflection units, such as a semiconductor laser according to the embodiment, there may be problems such as a narrow FSR due to the presence of various longitudinal modes and occurrence of a multimode oscillation.

However, in the semiconductor laser according to the embodiment, by designing χ and L_{Φ} to appropriate values based on Equation (12), good resonance characteristics comparable to those of a simple isolated resonator composed of only two reflectors, that is, a sufficiently wide FSR and single mode oscillating properties can be obtained.

Specifically, this design method assumes appropriate values for χ and L_{Φ} and substitutes them into Equation (12), and the resulting c₁₁ are plotted as shown in FIGS. 6A, 6B, and 6C to numerically confirm the wavelength that satisfies the resonance condition.

Next, a Q value and a light extraction efficiency in the resonator of the semiconductor laser according to the embodiment will be described. The Q value of the resonator is important to obtain a low threshold oscillation of the laser. Here, in order to discuss the resonator Q value as a passive dielectric structure, it is assumed that the active layer 109 is in a transparent condition, and β_{A} and β_{B} are both real numbers. Then, from Equations (9) and (12), the passive power gain per round trip of the resonance mode is obtained by Equation (13) below.

$$\begin{matrix}Math . 12 & \\ {a}^{2} = {\vert {c}_{11} \vert}^{2} = {\vert {r}_{F , A} \vert}^{2} {\vert {r}_{R , A} \vert}^{2} {\vert {\{ cos ( {qL}_{c} ) + j \frac{δ}{q} sin ( q {L}_{c} ) \}}^{2} - \frac{{χ}^{2}}{{q}^{2}} {sin}^{2} ( q {L}_{c} ) {e}^{- 2 j {β}_{Φ} {L}_{Φ}} \vert}^{2} & ( 13 )\end{matrix}$$

Here, assuming that the effective group refractive index of the resonance mode is n_{q,eff} and the effective resonator length is L_{eff}, the resonator Q value can be approximately represented by Equation (14) below based on the Fabry-Perot picture.

$$\begin{matrix}Math . 13 & \\ {Q}_{cav} = \frac{2 ω {n}_{g , eff} {L}_{eff}}{- c log ( {\vert {c}_{11} \vert}^{2} )} & ( 14 )\end{matrix}$$

Here, c is the speed of light in vacuum and ω is the resonance angular frequency. Substituting Equation (13) into Equation (14) reveals that the resonator Q-value can be resolved into two Q-values as follows.

$$\begin{matrix}Math . 14 & \\ {Q}_{cav} = \frac{1}{\frac{1}{{Q}_{F . P .}} + \frac{1}{{Q}_{output}}} & ( 15 )\end{matrix}$$

$${Q}_{F . P .} = \frac{2 ω {n}_{g , eff} {L}_{eff}}{- c log ( {\vert {r}_{F , A} \vert}^{2} {\vert {r}_{R , A} \vert}^{2} )} \qquad ( 16 )$$

$${Q}_{output} = \frac{2 ω {n}_{g , eff} {L}_{eff}}{- c log [ {\vert {\{ cos ( {qL}_{c} ) + j \frac{δ}{q} sin ( q {L}_{c} ) \}}^{2} - \frac{{χ}^{2}}{{q}^{2}} {sin}^{2} ( q {L}_{c} ) {e}^{- 2 j {β}_{Φ} {L}_{Φ}} \vert}^{2} ]} \qquad ( 17 )$$

Here, Q_{F.P.} is a Q value as a simple Fabry-Perot resonator caused by the fact that the front and rear mirrors have a finite reflectance of less than 100%. On the other hand, Qₒᵤₜₚᵤₜ represents the effect that a part of the resonant optical electric field is taken out as a traveling wave component toward the front side of the second optical waveguide B as a result of interference in the coupling region 132, and thereby the Q value is lowered. Therefore, if the factor of the optical loss in the resonator is only of these two passive structures, the light extraction efficiency of the resonator can be obtained by Equation (18) below. In an actual device, there may be other factors such as absorption loss due to impurities.

$$\begin{matrix}Math . 15 & \\ {η}_{output} = \frac{\frac{1}{{Q}_{output}}}{\frac{1}{{Q}_{F . P .}} + \frac{1}{{Q}_{output}}} & ( 18 )\end{matrix}$$

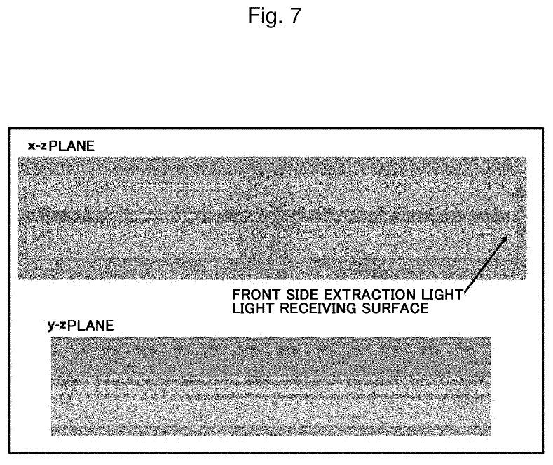

In order to confirm the correctness of the analytical handling based on the model illustrated in FIG. 5, numerical simulations under the same structure were performed by the three-dimensional finite-difference time-domain method (3D-FDTD method). The simulation setup is illustrated in FIG. 7. Here, assuming that the laser is operated by a diode, a semiconductor layer for current injection as illustrated in FIG. 4 is provided.

In a case where the 3D-FDTD is used, the resonator Q value can be determined from a time constant representing the temporal attenuation of the optical field intensity in the resonance mode. As for the light extraction efficiency, the light receiving surface as illustrated in FIG. 7 is arranged on the front side of the second optical waveguide B, and the flux of the pointing vector passing through this surface is transmitted to the second optical waveguide B, And the total flux of the closed surface surrounding the whole simulation region is divided by the total flux of the closed surface surrounding the whole simulation region.

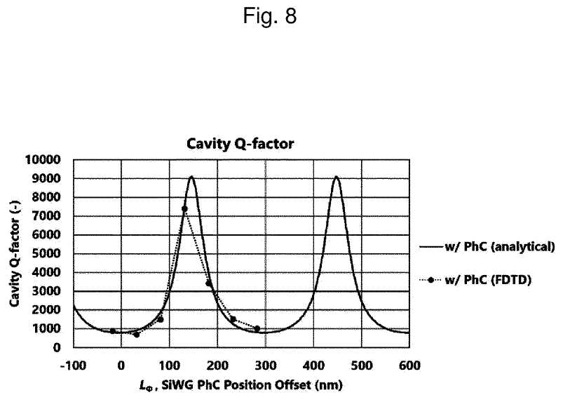

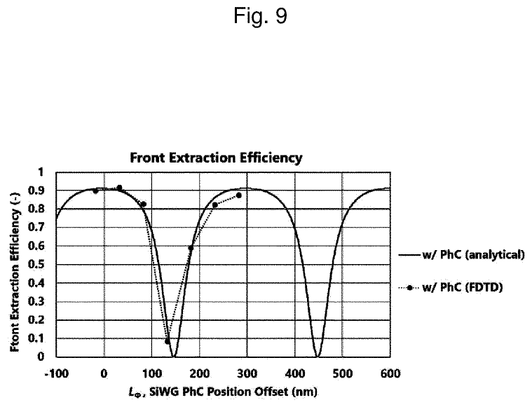

The L_{Φ} dependency of the resonator Q value calculated by the analytical model of FIG. 5 and the 3D-FDTD of FIG. 7 is illustrated in FIG. 8, and the L_{Φ} dependency of the light extraction efficiency is illustrated in FIG. 9. In any figures, the analytical calculation and the 3D-FDTD show the characteristics which quantitatively match, and the correctness of the calculation can be confirmed. Both the resonator Q value and the light extraction efficiency show behavior of periodically variation with respect to L_{Φ}. This corresponds to a phase change in the phase adjustment region of the second optical waveguide B, and this period is given by ΔL_{Φ}=π/β_{Φ}. In particular, at the minimum point of the resonator Q value (=maximum light extraction efficiency) given by L_{Φ}=(π/β_{Φ}) m (m is an integer), the condition that the reflected wave from the rear side of the first optical waveguide A and the reflected wave from the rear side of the second optical waveguide B completely strengthen each other on the front side of the second optical waveguide B is satisfied, and a light extraction Q value of Equation (15) is given by Equation (19) below.

$$\begin{matrix}Math . 16 & \\ {Q}_{output} = \frac{2 ω {n}_{g , eff} {L}_{eff}}{- c log \{ 1 - \frac{{χ}^{2}}{{q}^{2}} {sin}^{2} ( q {L}_{c} ) \}} & ( 19 )\end{matrix}$$

Therefore, by designing the resonator structure so as to satisfy L_{Φ}=(π/β_{Φ})m, the maximum light extraction efficiency can be obtained. Furthermore, at that time, by setting various parameters such as χ, q, Lc, and L_{eff} to appropriate values based on Equation (19), a resonator having a desired light extraction Q value can be designed.

On the other hand, at the maximum point of the resonator Q value (=the minimum point of the light extraction efficiency) given by L_{Φ}=(π/β_{Φ) (m+}½) (m is an integer), the condition that the reflected wave from the rear side of the first optical waveguide A and the reflected wave from the rear side of the second optical waveguide B completely weaken each other on the front side of the second optical waveguide B is satisfied, 1/Qₒᵤₜₚᵤₜ=0 is established, and ideally no light is output from the front side of the second optical waveguide B at all.

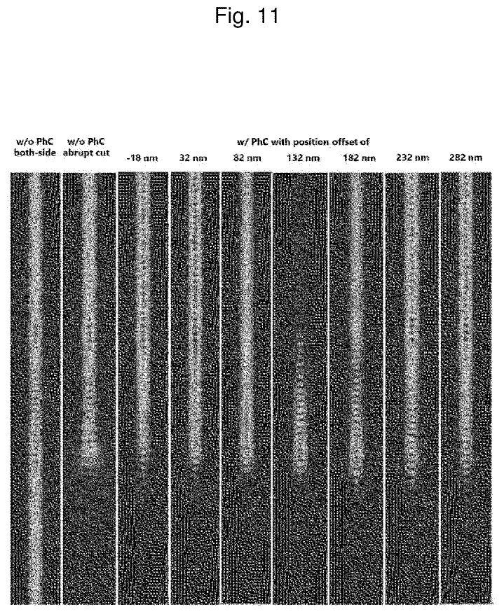

FIGS. 10 and 11 illustrate the optical electric field intensity distribution of the resonance mode obtained by performing the 3D-FDTD calculation with the setup of FIG. 7. FIG. 10 illustrates a y-z cross-section of the first optical waveguide A at the center of the x-coordinate and the second optical waveguide B and FIG. 11 illustrates an x-z cross-section of the second optical waveguide B at the center of the y coordinate.

Here, for comparison, estimation can be made for the case where the second optical waveguide B does not have the third reflecting unit 131 and has a symmetrical emission structure on both sides (leftmost column) and the case where the second optical waveguide B is cut off at the position of the rear end of the confinement portion 103 (the coupling region 132) and the second optical waveguide B exists only on the front side (second column from the left). The second optical waveguide B in which the third reflection unit 131 is formed (seven columns on the right side) corresponds to the plotted points in FIGS. 8 and 9. However, as discussed above, it can be seen that the light intensity on the front side of the second optical waveguide B changes systematically depending on the interference conditions.

On the rear side of the second optical waveguide B, reflection by the third reflection unit 131 occurs, and the intensity of the optical electric field is attenuated, and it is found that the optical electric field oozes out into the third reflection unit 131. On the other hand, in the two-side symmetrical emission structure, optical electric fields having the same intensity are surely output to both the front side and the rear side. Further, in the rear side cut-off structure, the second optical waveguide B is configured to exist only on the front side, but on a cut-off surface of the second optical waveguide B on the rear side, It can be seen that the light is emitted backward.

The resonator Q value and the light extraction efficiency obtained at this time are Q_{cav}=2.00×10³ and ηₒᵤₜₚᵤₜ=35.4%. In the rear-side cutting structure, Q_{cav}=1.71×10³ and ηₒᵤₜₚᵤₜ=38.0% are established. In either case, the light extraction efficiency on the front side is lower than 50% due to the output emission to the rear side.

On the other hand, in the structure having the third reflection unit 131 on the rear side, although the resonator Q value is equivalent as illustrated in FIGS. 8 and 9, high light extraction efficiency over 80% and 90% can be obtained, and thus, the effect of the present invention can be confirmed.

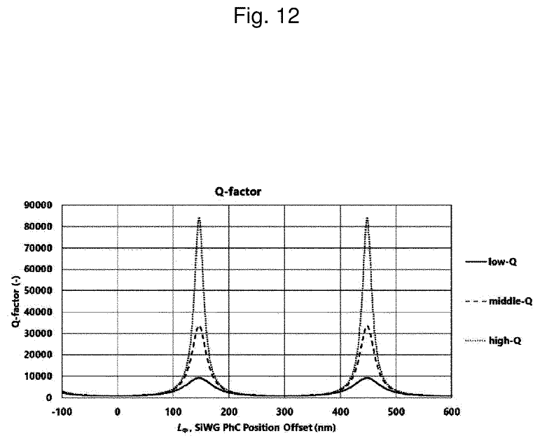

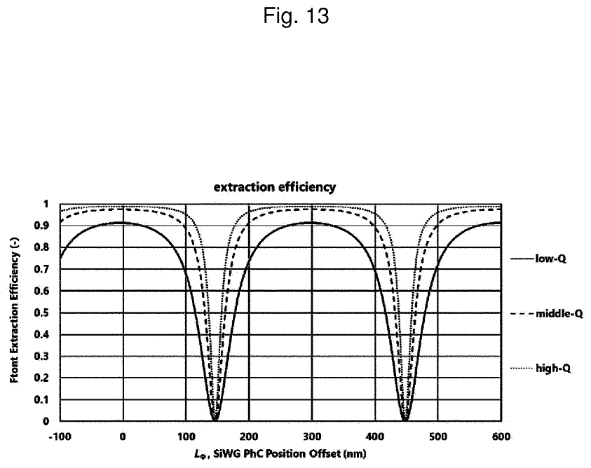

Next, the values of the reflectances |r_{F,A}|² and |r_{R,A}|² of the third reflection unit 131 are changed, and the resonator characteristics when changing the isolated resonator Q value as the Fabry-Perot resonator given by Equation (16) are illustrated in FIGS. 12 and 13. In these figures, three levels of low-Q: |r_{F,A}|²=|r_{R,A}|²=0.9926, middle-Q: |r_{F,A}|²=|r_{R,A}|²=0.9980, and high-Q: |r_{F,A}|²=|r_{R,A}|²=0.9992 are plotted.

From FIG. 13, in order to obtain the high light extraction efficiency, it is not always necessary to accurately satisfy the above perfect constructive condition, and detuning δL_{Φ} from the perfect constructive condition such as L_{Φ}(π/β_{Φ})m±δL_{Φ} may be superimposed.

Further, it is found that the limit value of detuning δL_{Φ} allowable for obtaining a certain desired light extraction efficiency increases as the isolated resonator Q value increases. This is because the ratio of the light extraction loss 1/Qₒᵤₜₚᵤₜ relatively increases as the isolated resonator Q value Q_{F.P.} increases, as expressed by Equation (18). For example, in the case of middle-Q, even if δL_{Φ}=100 nm, the high light extraction efficiency is obtained which extends to approximately 90%.

According to the embodiment, the second reflection unit 102 of the first optical waveguide A and the third reflection unit 131 on the second optical waveguide B side are manufactured by separate processes. Therefore, in the substrate plane direction (x-y direction), a positional deviation may occur between the two. If the deviation amount is equal to or less than the limit value of the detuning, the characteristic variation is suppressed to be small, and high light extraction efficiency is stably obtained. The alignment accuracy with the deviation amount of 100 nm or less can be easily achieved with the current microfabrication technology.

In the above description, as described with reference to FIGS. 1A to 1C, 2A to 2C, and 3A and 3B, although the case where the first reflection unit 101, the second reflection unit 102, and the third reflection unit 131 have the same structure has been described, the present invention is not limited thereto. For example, a reflection structure by a one-dimensional photonic crystal and a reflection structure by a diffraction grating formed on the upper part can be combined. The reflection structure by the one-dimensional photonic crystal and the reflection structure by the diffraction grating formed on the side part can be combined. The reflection structure by the diffraction grating formed on the upper part and the reflection structure by the one-dimensional photonic crystal can be combined. The first reflection unit 101, the second reflection unit 102, and the third reflection unit 131 can be combined with any reflection structure.

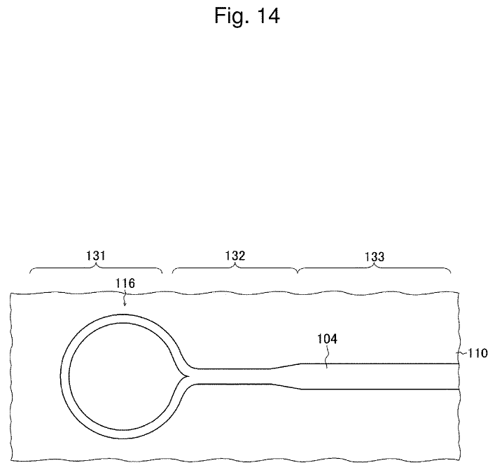

Further, as illustrated in FIG. 14, the third reflection unit 131 may be configured by a loop rear view mirror 116. In this case, the formation of the second optical waveguide B and the formation of the third reflection unit 131 can be simultaneously performed in one manufacturing process, and the manufacturing becomes easier than the case described by using FIG. 1A to 1C and FIG. 2A to 2C.

On the other hand, if both DBRs have the same structure as in FIGS. 1A to 1C, 2A to 2C, and 3A and 3B, the following advantages are obtained.
1. Since the reflection characteristics of each are almost identical (actually, since the equivalent refractive index is shifted so as not to cause optical coupling, a slight difference in characteristics may occur due to this), a slight difference in the characteristics caused by the shift can occur, the phase adjustment length L_{Φ} can be regarded as being substantially equal to the difference in the start position of each reflection unit, which facilitates control of the interference condition.
2. In particular, in a case where the reflection structure by the one-dimensional photonic crystal is used, the length of the reflection unit can be shortened to the order of micron length on both the first optical waveguide A side and the second optical waveguide B side, and the whole device structure including the light extraction mechanism can be realized extremely compactly.

As described above, according to the present invention, since the third reflection unit is provided in the second optical waveguide disposed along the first optical waveguide having the confinement portion in which the active layer is formed, the loss of the optical power of the semiconductor laser can be prevented.

According to the present invention, the high efficiency of light extraction can be obtained. In the present invention, since the rear side output in the conventional both-side emission structure is reflected to the front side, high-efficiency one-side emission free from wasted light loss is realized, and high front side light extraction efficiency ranging from 80% to 90% can be realized. In the conventional typical double-sided symmetrical emission structure, the light extraction efficiency on one side must be 50% or less in principle, but the limit can be broken by the present invention.

Further, according to the present invention, a single mode property can be easily obtained. In general, in a laser having three or more reflection units, various longitudinal modes may exist, and the problem that the FSR becomes narrow or multi-mode oscillation occurs may arise. However, according to the present invention, by appropriately setting parameters such as χ and L_{Φ}, it is possible to suppress the occurrence of an excessive longitudinal mode due to the third reflection unit on the side of the second optical waveguide, and to obtain an FSR sufficiently wide for obtaining single mode oscillation.

Further, according to the present invention, the semiconductor laser can be formed more compactly. For example, by configuring the reflection unit of a waveguide type one-dimensional photonic crystal, very strong light confinement is enabled, the length of the entire device structure including a light extraction mechanism can be shortened to the order of micron length, and a semiconductor laser which is extremely compact as a whole can be realized.

As a comparison, when light is transferred from a first optical waveguide (for example, a group III-V compound semiconductor layer) to a second optical waveguide (for example, an embedded Si layer), although a structure in which light is first output to an optical waveguide on the front side of the first optical waveguide and the light is transferred to the second optical waveguide by a tapered structure is also often used, in this case, a tapered length of about several hundred microns is typically required to transfer the light to a low loss. In the present invention, it is not necessary to use such a long taper structure, and it is possible to realize the optical waveguide device in the order of micron length including a structure for transferring light from the first optical waveguide to the second optical waveguide layer.

Further, according to the present invention, design for obtaining desired characteristics is easy. In the present invention, in order to obtain desired characteristics (a single mode property, a resonator Q value, a light extraction efficiency, and the like), the coupling strength between the first optical waveguide and the second optical waveguide in the coupling region, and an interference condition between a reflected wave from the rear side of the first optical waveguide and a reflected wave from the rear side of the second optical waveguide must be appropriately controlled and designed. In this design, in the present invention, the coupling of the first optical waveguide and the second optical waveguide in the coupling region is appropriately modeled by a directional coupler, and it is possible to analyze handling by structural parameters such as δ, χ, q, and L_{c}. Thus, the device structure design for obtaining a desired coupling strength is facilitated.

Further, by using reflection units having similar characteristics on both the first optical waveguide side and the second optical waveguide side, interference condition control between both reflection waves can be dropped into a single structural parameter of a phase adjustment length L_{Φ} given as a difference between start positions of the respective reflection units. If the reflection units having different reflection characteristics are used in both of them, it is necessary to consider the difference in the reflection characteristics when controlling the interference conditions, and the design items are relatively complicated.

Further, the present invention has resistance to positional deviation at the time of manufacturing between the first reflection unit of the first optical waveguide and the third reflection unit of the second optical waveguide. When the semiconductor laser according to the present invention is actually manufactured, a positional deviation in the direction of the substrate plane (x-z direction) may occur between the first reflection unit of the first optical waveguide and the third reflection unit of the second optical waveguide. It is conceivable that the interference condition between the reflected waves of the two is deviated from an accurate target due to the positional deviation.

However, in the present invention, since there is no wasted light loss, even if the interference condition does not exactly satisfy the full constructive condition on the front side of the second optical waveguide, the light extraction efficiency (that is, the ratio of light extraction loss to total light loss) remains high. That is, this means that the present invention has resistance to misalignment during fabrication, and stably obtains high light extraction efficiency even if misalignment occurs. In one example described above, when the deviation of the relative position in the z-direction (waveguiding direction) is within ±100 nm, the high light extraction efficiency of 90% or more can be always obtained. The alignment accuracy with the deviation amount of 100 nm or less can be easily achieved with the current microfabrication technology.

In the present invention, it is important to realize a truly high-efficiency light extraction mechanism by focusing on and solving the problem that the light loss due to the emission of the rear side has not been solved in the prior art. In the conventional study, the sum of the front side output and the rear side output is defined as a net output in calculating the light extraction efficiency, but this definition is not suitable because only the front side output is used in typical information transmission applications.

In addition, in the present invention, it is important to analytically formulate the behavior of the first optical waveguide using an appropriate model using a directional coupler and clearly describe important device characteristics such as single mode property, Q value in the cavity of the first optical waveguide, and light extraction efficiency. Thus, it is possible to guarantee single mode oscillation property and to facilitate the design of the first optical waveguide characteristic.

Further, the present invention is also important in that the entire device structure including the light extraction mechanism can be realized in an extremely compact size of the order of micron length. This is an advantage obtained by using a reflection structure of a waveguide type one-dimensional photonic crystal in the third reflection unit on the second optical waveguide side.

Further, in the present invention, it is also important that the first optical waveguide characteristics have high resistance to positional deviation during device fabrication. The light extraction mechanism has a high efficiency without wasted light loss, while having a dense structure utilizing interference of light, and has resistance to sufficiently absorb positional deviation which may occur in an actual manufacturing process.

Also, it is apparent that the present invention is not limited to the embodiment described above, and many modifications and combinations can be carried out by those having ordinary knowledge in the art within the technical idea of the present invention.

### REFERENCE SIGNS LIST

101 First reflection unit
102 Second reflection unit
103 Confinement portion
104 Core
105 First base
106 First lattice element
107 Second base
108 Second lattice element
109 Active layer
110 Lower clad layer
111 Upper clad layer
112 Third lattice element
131 Third reflection unit
132 Coupling region
133 Emission side region
A First optical waveguide
B Second optical waveguide

1. A semiconductor laser comprising:
a first optical waveguide including a waveguide-type first and second reflection units each having a structure in which a refractive index is periodically modulated, and a confinement portion sandwiched between the first reflection unit and the second reflection unit;
a second optical waveguide disposed along the first optical waveguide to extend from the confinement portion toward the second reflection unit side;
a third reflection unit formed continuously with the second optical waveguide at a location corresponding to the first reflection unit; and
an active layer formed in the confinement portion,
wherein
a Fabry-Perot optical resonator is configured by the first reflection unit, the confinement portion, and the second reflection unit, and
in a coupling region where the confinement portion is disposed, the second optical waveguide and the confinement portion are in a state capable of optically coupling with each other, and
a laser is output to the side of the second reflection unit of the second optical waveguide.

2. The semiconductor laser according to claim 1, wherein
a difference between an equivalent refractive index of the second reflection unit and an equivalent refractive index of a core of the second optical waveguide in a region corresponding to the second reflection unit is larger than a difference between an equivalent refractive index of the confinement portion and an equivalent refractive index of a core of the second optical waveguide in the coupling region.

3. The semiconductor laser according to claim 2, wherein
the core of the second optical waveguide in the coupling region has a diameter different from that of the core of the second optical waveguide in a region corresponding to the second reflection unit.

4. The semiconductor laser according to claim 3, wherein
a diameter of a core of the second optical waveguide gradually changes from the coupling region to a region corresponding to the second reflection unit.

5. The semiconductor laser according to claim 2, wherein
a width of the confinement portion in a plan view differs from a width of the second reflection unit in a plan view.

6. The semiconductor laser according to claim 5, wherein
the width of the confinement portion in a plan view gradually changes to the second reflection unit.

7. The semiconductor laser according to claim 1, wherein
the first reflection unit and the second reflection unit are configured of a waveguide-type one-dimensional photonic crystal.

8. A method of designing the semiconductor laser according to claim 1, the method comprising:
setting, when a position offset in a waveguide direction between the first reflection unit and the third reflection unit is denoted as L_{Φ},
a propagation constant of a portion of the length LΦ in the second optical waveguide of a portion of a position offset in a waveguide direction between the first reflection unit and the third reflection unit is denoted as βΦ,
a propagation constant of the coupling region in the first optical waveguide is denoted as βA, and
a propagation constant of the coupling region in the second optical waveguide is denoted as β_{B},
Math. 1
The endpoint of the coupling region on the laser output side is denoted as subscript F, the endpoint on the opposite side is denoted as subscript R, in an optical electric field in the first optical waveguide and the second optical waveguide in the coupling region, forward wave components are denoted as \vec{A_{F}}, \vec{A_{R}}, \vec{B_{F}}, and \vec{B_{R}}, and backward wave components are denoted as [symbol] , [symbol] , [symbol] , and [symbol] and following equations are provided:
$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} and$$
$$( \begin{matrix}\vec{{A}_{F}} \\ \vec{{B}_{F}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( A )$$
$${c}_{11} = {r}_{F , A} {r}_{R , A} [ {\{ cos ( {qL}_{c} ) + j \frac{δ}{q} sin ( {qL}_{c} ) \}}^{2} - \frac{{χ}^{2}}{{q}^{2}} {sin}^{2} ( q {L}_{c} ) {e}^{- 2 j {β}_{Φ} {L}_{Φ}} ]$$
$${e}^{- j ( {β}_{A} + {β}_{B} ) {L}_{c}} , \qquad ( B )$$
a condition so that a state of a wavelength satisfying a resonance condition obtained on a basis of wavelength characteristics of c₁₁ obtained by changing χ and L_{Φ}satisfies a single mode condition based on Equations A and B.

9. The semiconductor laser according to claim 2, wherein
the first reflection unit and the second reflection unit are configured of a waveguide-type one-dimensional photonic crystal.

10. The semiconductor laser according to claim 3, wherein
the first reflection unit and the second reflection unit are configured of a waveguide-type one-dimensional photonic crystal.

11. The semiconductor laser according to claim 4, wherein
the first reflection unit and the second reflection unit are configured of a waveguide-type one-dimensional photonic crystal.

12. The semiconductor laser according to claim 5, wherein
the first reflection unit and the second reflection unit are configured of a waveguide-type one-dimensional photonic crystal.

13. The semiconductor laser according to claim 6, wherein
the first reflection unit and the second reflection unit are configured of a waveguide-type one-dimensional photonic crystal.

14. A method of designing the semiconductor laser according to claim 2, the method comprising:
setting, when a position offset in a waveguide direction between the first reflection unit and the third reflection unit is denoted as L_{Φ},
a propagation constant of a portion of the length LΦ in the second optical waveguide of a portion of a position offset in a waveguide direction between the first reflection unit and the third reflection unit is denoted as βΦ,
a propagation constant of the coupling region in the first optical waveguide is denoted as βA, and
a propagation constant of the coupling region in the second optical waveguide is denoted as β_{B},
Math. 1
The endpoint of the coupling region on the laser output side is denoted as subscript F, the endpoint on the opposite side is denoted as subscript R, in an optical electric field in the first optical waveguide and the second optical waveguide in the coupling region, forward wave components are denoted as \vec{A_{F}}, \vec{A_{R}}, \vec{B_{F}}, and \vec{B_{R}}, and backward wave components are denoted as [symbol] , [symbol] , [symbol] , and [symbol] and following equations are provided:
$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} and$$
$$( \begin{matrix}\vec{{A}_{F}} \\ \vec{{B}_{F}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( A )$$
$${c}_{11} = {r}_{F , A} {r}_{R , A} [ {\{ cos ( {qL}_{c} ) + j \frac{δ}{q} sin ( {qL}_{c} ) \}}^{2} - \frac{{χ}^{2}}{{q}^{2}} {sin}^{2} ( q {L}_{c} ) {e}^{- 2 j {β}_{Φ} {L}_{Φ}} ]$$
$${e}^{- j ( {β}_{A} + {β}_{B} ) {L}_{c}} , \qquad ( B )$$
a condition so that a state of a wavelength satisfying a resonance condition obtained on a basis of wavelength characteristics of c₁₁ obtained by changing χ and L_{Φ} satisfies a single mode condition based on Equations A and B.

15. A method of designing the semiconductor laser according to claim 3, the method comprising:
setting, when a position offset in a waveguide direction between the first reflection unit and the third reflection unit is denoted as L_{Φ},
a propagation constant of a portion of the length LΦ in the second optical waveguide of a portion of a position offset in a waveguide direction between the first reflection unit and the third reflection unit is denoted as βΦ,
a propagation constant of the coupling region in the first optical waveguide is denoted as βA, and
a propagation constant of the coupling region in the second optical waveguide is denoted as β_{B},
Math. 1
The endpoint of the coupling region on the laser output side is denoted as subscript F, the endpoint on the opposite side is denoted as subscript R, in an optical electric field in the first optical waveguide and the second optical waveguide in the coupling region, forward wave components are denoted as \vec{A_{F}}, \vec{A_{R}}, \vec{B_{F}}, and \vec{B_{R}}, and backward wave components are denoted as [symbol] , [symbol] , [symbol] , and [symbol] and following equations are provided:
$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} and$$
$$( \begin{matrix}\vec{{A}_{F}} \\ \vec{{B}_{F}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( A )$$
$${c}_{11} = {r}_{F , A} {r}_{R , A} [ {\{ cos ( {qL}_{c} ) + j \frac{δ}{q} sin ( {qL}_{c} ) \}}^{2} - \frac{{χ}^{2}}{{q}^{2}} {sin}^{2} ( q {L}_{c} ) {e}^{- 2 j {β}_{Φ} {L}_{Φ}} ]$$
$${e}^{- j ( {β}_{A} + {β}_{B} ) {L}_{c}} , \qquad ( B )$$
a condition so that a state of a wavelength satisfying a resonance condition obtained on a basis of wavelength characteristics of c₁₁ obtained by changing χ and L_{Φ} satisfies a single mode condition based on Equations A and B.

16. A method of designing the semiconductor laser according to claim 4, the method comprising:
setting, when a position offset in a waveguide direction between the first reflection unit and the third reflection unit is denoted as L_{Φ},
a propagation constant of a portion of the length LΦ in the second optical waveguide of a portion of a position offset in a waveguide direction between the first reflection unit and the third reflection unit is denoted as βΦ,
a propagation constant of the coupling region in the first optical waveguide is denoted as βA, and
a propagation constant of the coupling region in the second optical waveguide is denoted as β_{B},
Math. 1
The endpoint of the coupling region on the laser output side is denoted as subscript F, the endpoint on the opposite side is denoted as subscript R, in an optical electric field in the first optical waveguide and the second optical waveguide in the coupling region, forward wave components are denoted as \vec{A_{F}}, \vec{A_{R}}, \vec{B_{F}}, and \vec{B_{R}}, and backward wave components are denoted as [symbol] , [symbol] , [symbol] , and [symbol] and following equations are provided:
$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} and$$
$$( \begin{matrix}\vec{{A}_{F}} \\ \vec{{B}_{F}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( A )$$
$${c}_{11} = {r}_{F , A} {r}_{R , A} [ {\{ cos ( {qL}_{c} ) + j \frac{δ}{q} sin ( {qL}_{c} ) \}}^{2} - \frac{{χ}^{2}}{{q}^{2}} {sin}^{2} ( q {L}_{c} ) {e}^{- 2 j {β}_{Φ} {L}_{Φ}} ]$$
$${e}^{- j ( {β}_{A} + {β}_{B} ) {L}_{c}} , \qquad ( B )$$
a condition so that a state of a wavelength satisfying a resonance condition obtained on a basis of wavelength characteristics of c₁₁ obtained by changing χ and L_{Φ} satisfies a single mode condition based on Equations A and B.

17. A method of designing the semiconductor laser according to claim 5, the method comprising:
setting, when a position offset in a waveguide direction between the first reflection unit and the third reflection unit is denoted as L_{Φ},
a propagation constant of a portion of the length LΦ in the second optical waveguide of a portion of a position offset in a waveguide direction between the first reflection unit and the third reflection unit is denoted as βΦ,
a propagation constant of the coupling region in the first optical waveguide is denoted as βA, and
a propagation constant of the coupling region in the second optical waveguide is denoted as β_{B},
Math. 1
The endpoint of the coupling region on the laser output side is denoted as subscript F, the endpoint on the opposite side is denoted as subscript R, in an optical electric field in the first optical waveguide and the second optical waveguide in the coupling region, forward wave components are denoted as \vec{A_{F}}, \vec{A_{R}}, \vec{B_{F}}, and \vec{B_{R}}, and backward wave components are denoted as [symbol] , [symbol] , [symbol] , and [symbol] and following equations are provided:
$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} and$$
$$( \begin{matrix}\vec{{A}_{F}} \\ \vec{{B}_{F}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( A )$$
$${c}_{11} = {r}_{F , A} {r}_{R , A} [ {\{ cos ( {qL}_{c} ) + j \frac{δ}{q} sin ( {qL}_{c} ) \}}^{2} - \frac{{χ}^{2}}{{q}^{2}} {sin}^{2} ( q {L}_{c} ) {e}^{- 2 j {β}_{Φ} {L}_{Φ}} ]$$
$${e}^{- j ( {β}_{A} + {β}_{B} ) {L}_{c}} , \qquad ( B )$$
a condition so that a state of a wavelength satisfying a resonance condition obtained on a basis of wavelength characteristics of c₁₁ obtained by changing χ and L_{Φ} satisfies a single mode condition based on Equations A and B.

18. A method of designing the semiconductor laser according to claim 6, the method comprising:
setting, when a position offset in a waveguide direction between the first reflection unit and the third reflection unit is denoted as L_{Φ},
a propagation constant of a portion of the length LΦ in the second optical waveguide of a portion of a position offset in a waveguide direction between the first reflection unit and the third reflection unit is denoted as βΦ,
a propagation constant of the coupling region in the first optical waveguide is denoted as βA, and
a propagation constant of the coupling region in the second optical waveguide is denoted as β_{B},
Math. 1
The endpoint of the coupling region on the laser output side is denoted as subscript F, the endpoint on the opposite side is denoted as subscript R, in an optical electric field in the first optical waveguide and the second optical waveguide in the coupling region, forward wave components are denoted as \vec{A_{F}}, \vec{A_{R}}, \vec{B_{F}}, and \vec{B_{R}}, and backward wave components are denoted as [symbol] , [symbol] , [symbol] , and [symbol] and following equations are provided:
$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} and$$
$$( \begin{matrix}\vec{{A}_{F}} \\ \vec{{B}_{F}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( A )$$
$${c}_{11} = {r}_{F , A} {r}_{R , A} [ {\{ cos ( {qL}_{c} ) + j \frac{δ}{q} sin ( {qL}_{c} ) \}}^{2} - \frac{{χ}^{2}}{{q}^{2}} {sin}^{2} ( q {L}_{c} ) {e}^{- 2 j {β}_{Φ} {L}_{Φ}} ]$$
$${e}^{- j ( {β}_{A} + {β}_{B} ) {L}_{c}} , \qquad ( B )$$
a condition so that a state of a wavelength satisfying a resonance condition obtained on a basis of wavelength characteristics of c₁₁ obtained by changing χ and L_{Φ} satisfies a single mode condition based on Equations A and B.

19. A method of designing the semiconductor laser according to claim 7, the method comprising:
setting, when a position offset in a waveguide direction between the first reflection unit and the third reflection unit is denoted as L_{Φ},
a propagation constant of a portion of the length LΦ in the second optical waveguide of a portion of a position offset in a waveguide direction between the first reflection unit and the third reflection unit is denoted as βΦ,
a propagation constant of the coupling region in the first optical waveguide is denoted as βA, and
a propagation constant of the coupling region in the second optical waveguide is denoted as β_{B},
Math. 1
The endpoint of the coupling region on the laser output side is denoted as subscript F, the endpoint on the opposite side is denoted as subscript R, in an optical electric field in the first optical waveguide and the second optical waveguide in the coupling region, forward wave components are denoted as \vec{A_{F}}, \vec{A_{R}}, \vec{B_{F}}, and \vec{B_{R}}, and backward wave components are denoted as [symbol] , [symbol] , [symbol] , and [symbol] and following equations are provided:
$$δ = \frac{{β}_{B} - {β}_{A}}{2} , q = \frac{\vert {β}_{B}^{′} - {β}_{A}^{′} \vert}{2} , χ = \sqrt{{q}^{2} - {δ}^{2}} and$$
$$( \begin{matrix}\vec{{A}_{F}} \\ \vec{{B}_{F}}\end{matrix} ) ≡ ( \begin{matrix}{c}_{11} & {c}_{12} \\ {c}_{21} & {c}_{22}\end{matrix} ) ( \begin{matrix}\vec{{A}_{F , 0}} \\ \vec{{B}_{F , 0}}\end{matrix} ) \qquad ( A )$$
$${c}_{11} = {r}_{F , A} {r}_{R , A} [ {\{ cos ( {qL}_{c} ) + j \frac{δ}{q} sin ( {qL}_{c} ) \}}^{2} - \frac{{χ}^{2}}{{q}^{2}} {sin}^{2} ( q {L}_{c} ) {e}^{- 2 j {β}_{Φ} {L}_{Φ}} ]$$
$${e}^{- j ( {β}_{A} + {β}_{B} ) {L}_{c}} , \qquad ( B )$$
a condition so that a state of a wavelength satisfying a resonance condition obtained on a basis of wavelength characteristics of c₁₁ obtained by changing χ and L_{Φ} satisfies a single mode condition based on Equations A and B.
